(19) United States
(12) Patent Application Publication
(10) Pub. No.: US 2011/0108108 A1
(43) Pub. Date: May 12, 2011

(54) FLASH LIGHT ANNEALING FOR THIN FILMS

(75) Inventors: James S. Im, New York, NY (US); Paul C. Van Der Wilt, New York, NY (US); Ui-Jin Chung, Rego Park, NY (US)

(73) Assignee: The Trustees of Columbia University in the City of, New York, NY (US)

(21) Appl. No.: 12/919,687

(22) PCT Filed: Feb. 27, 2009
(86) PCT No.: PCT/US09/35537

§ 371 Date: Jan. 25, 2011

Related U.S. Application Data
(60) Provisional application No. 61/032,781, filed on Feb. 29, 2008.
(60) Provisional application No. 61/111,518, filed on Nov. 5, 2008.

(51) Int. Cl. H01L 31/0368; H01L 21/26; H01L 31/18; H01L 29/04

(52) U.S. Cl. 136/258; 438/795; 438/97; 257/75; 257/E21.328; 257/E31.043; 257/E29.003

(57) ABSTRACT

A method of making a crystalline film includes providing a film comprising seed grains of a selected crystallographic surface orientation on a substrate; irradiating the film using a pulsed light source to provide pulsed melting of the film under conditions that provide a mixed liquid/solid phase and allowing the mixed solid/liquid phase to solidify under conditions that provide a textured polycrystalline layer having the selected surface orientation. One or more irradiation treatments may be used. The film is suitable for use in solar cells.

### RELATED APPLICATIONS

This application is related to co-pending, commonly owned application Ser. No. 61/111,518, filed Nov. 5, 2008, and Ser. No. 61/032,781, filed Feb. 29, 2008, and incorporated in its entirety by reference.

### FIELD

The disclosed subject matter generally relates to crystallization of thin films and particularly relates to using a pulsed flood light source in such crystallization.

### BACKGROUND

Some solar cells use crystallized silicon films to conduct carriers. Solar cells use minor carriers, and in order to have a reasonable efficiency, they require films with a low defect density. The defects in a crystallized silicon film include grains boundaries, i.e., the boundaries between the crystallographic grains, as well as intragrain defects, i.e., the defects within the crystallographic grains, such as twin boundaries and stacking faults. To improve the efficiency of the solar cells, it is desirable to reduce the density of grain boundaries, that is, to increase the size of these grains, as well as reducing the density of intragrain defects.

Presently the most common method of making solar cells employs single crystal silicon (c-Si) substrates. These wafers provide a high quality substrate, but are expensive due to limited silicon feedstock availability. Polycrystalline silicon (poly-Si) substrates, e.g., from ingots, can be used but have only slightly lower cost. The current trend is to reduce the thickness of the c-Si and poly-Si wafer-based solar cells (for example below 200 μm); however, challenges arise regarding the mechanical properties of such wafers, for example in handling during processing.

Thin-film amorphous and/or nanocrystalline silicon solar cells use significantly less silicon, which has a potential cost advantage. Furthermore, they can be deposited on large-area substrates such as glass, metal foils, or even plastics. However, amorphous silicon still suffers from poor stability and lower efficiency than crystalline silicon. Thin film polycrystalline solar cells could potentially form an attractive compromise by offering low cost through limited use of silicon, while offering high stability and efficiency through the use of crystalline silicon.

To form thin-film polycrystalline films, an amorphous silicon (a-Si) layer can be treated to induce crystallization, for example, using thermal annealing techniques. However, such solid phase crystallization methods are known to result in films with a high intragrain defect density, and furthermore, they require long time periods and high temperatures, making them less suitable for thermally sensitive substrates such as glass.

Poly-Si films have been prepared using a seed layer approach. This approach starts from a low cost large substrate and creates a thin seed crystalline layer on top of the substrate. Conventional methods of obtaining a crystalline seed layer include aluminum-induced crystallization. The method results in large grain growth, but introduces many intragrain defects, so much so that above a certain grain size (for example a few μm) the properties of the film are dominated by the intragrain defects. Thus, the layer acts like a small grained material. In addition, the texture that is achieved in the process is relatively poor, for example only 75% of the surface area is within 20 degrees of the {100} pole. In a subsequent step, a thick crystalline layer is grown from the seed layer using epitaxial growth methods, such as plasma enhanced chemical vapor deposition. Low temperature chemical vapor deposition methods, such as hot wire chemical vapor deposition (CVD), are attractive as they offer the potential of glass compatibility; however, at low temperatures, these methods require high quality {100} oriented surfaces for qualitative epitaxial growth.

Zone-melting recrystallization (ZMR) of Si films can result in the formation of large grained polycrystalline Si films having a preferential {100} surface orientation of the crystals. The films qualify as seed layers because they have a low defect density, that is, large grain sizes, and a low number of intragrain defects. Moreover, silicon films having a (100) surface texture can be prepared. Such a texture is preferred for most epitaxial growth processes performed at low temperatures. However, stable growth of these long (100) textured grains is typically only observed at very low scan rates that are not compatible with preferred low-cost substrates such as glass.

Flash lamp annealing (FLA) has been used to crystallize an amorphous silicon film. These lamps have a low cost and a high power. In FLA, the flash discharge lamps produce a short-time pulse of intense light that can be used to melt and recrystallize the silicon layer. The FLA techniques used up to now have resulted in crystallized silicon films with high defect densities. As a result, these films are not optimal for use in solar cells. Thus, practical techniques are still lacking for use of FLA methods to grow high quality crystalline films.

### SUMMARY

This application describes methods and systems for utilizing flash lamp annealing (FLA) and other low cost divergent light sources to crystallize films with large grains and low intragrain defect density.

In one embodiment, a method of making a crystalline film includes providing a film comprising seed grains with a substantially uniform crystallographic surface orientation on a substrate, irradiating the film using a pulsed light source to provide pulsed melting of the film under conditions to provide a plurality of solid sections and liquid sections extending throughout the thickness of the film, creating a mixed liquid/solid phase comprising one or more of the seed grains, and allowing the mixed solid/liquid phase to solidify from the seed grains to provide a textured polycrystalline layer having the crystallographic surface orientation of the seed grains. The method also can include providing a film, which includes providing an amorphous film and subjecting the amorphous film to a radiation-induced transformation to polycrystalline silicon prior to the creation of a mixed liquid/solid phase to provide a film comprising seed grains of the substantially uniform crystallographic surface orientation.

In one or more embodiments, the periodicity of the mixed liquid-solid phase has a periodicity approaching a critical solid-liquid coexistence length (λₗₛ).

In one or more embodiments, the selected surface orientation is a {100} plane.

In one or more embodiments, the resultant textured polycrystalline layer comprises about 90% of the surface area of the film having a {100} surface orientation within about 15° of the {100} pole, or the resultant textured polycrystalline layer comprises about 90% of the surface area of the film having a {100} surface orientation within about 10° of the {100} pole, or the resultant textured polycrystalline layer comprises about 90% of the surface area of the film having a {100} surface orientation within about 5° of the {100} pole.

In one or more embodiments, the conditions of irradiation are selected to provide an intensity of incident light to provide a periodicity of the liquid-solid phase that approaches λₗₛ.

In one or more embodiments, the pulsed divergent light source comprises a flash lamp or a laser diode.

In one or more embodiments, the film comprises silicon.

In one or more embodiments, the liquid content of the mixed solid/liquid phase is in the range of about 50 vol % to about 99 vol %, or about 80 vol % to about 99 vol %.

In one or more embodiments, the irradiating conditions are selected to have a liquid content of the mixed solid/liquid phase of greater than 80 vol % when the distance between seeds exceeds λₗₛ, or the intensity of the divergent light source pulse is selected to provide a mixed solid/liquid phase.

In one or more embodiments, the film thickness is in the range of about 50 nm to about 1 μm, or in the range of about 150 nm to about 500 nm.

In one or more embodiments, the method further includes epitaxially growing a thick silicon layer on the textured layer.

In one or more embodiments, the layer is exposed to a single flash lamp pulse, and the light source pulse provides a liquid/solid mix having at least about 90 vol % liquid.

In one or more embodiments, the layer is exposed to multiple light pulses, such as in 2-10 light pulses or 2-4 light pulses.

In one or more embodiments, the light source pulse provides a liquid/solid mix having at least about 50 vol % liquid.

In one or more embodiments, the energy intensity of the incident light is about 2-150 J/cm².

In one or more embodiments, the mixed liquid/solid phase is achieved by selection of energy density, pulse shape, dwell time, and wavelength of the light incident to the film.

In one or more embodiments, further comprises preheating the substrate prior to flash lamp irradiation.

In one or more embodiments, the light source is of a wavelength in the range of 400-900 nm, or the light source comprises white light, or the light source comprises light of a wavelength selected for absorption by the film, or the light source comprises light of a wavelength selected for absorption by one or more of an underlying heat absorption layer.

In one or more embodiments, further comprises providing a metal underlayer for the film, wherein the heat of the light source is at least partially absorbed by the metal layer.

In one or more embodiments, a barrier layer is disposed between the film and the metal layer to reduce interaction of the film with the metal layer.

In one or more embodiments, the metal layer is patterned to provide heat absorption in selected areas.

In one or more embodiments, the film is pretreated to provide seed grains of a selected orientation, and the seed grains provided by a method selected from the group consisting of solid phase anneal, pulsed laser crystallization and melt-mediated explosive growth.

In one or more embodiments, the pulsed laser source is a divergent light source.

In one or more embodiments mixed liquid/solid phase is irradiated with the pulsed light source.

In one or more embodiments, the film is divided into one or more isolated sections and can include one or more trenches proximate to one or more of the isolated sections.

In one or more embodiments, a method of making a crystalline film includes providing a film comprising seed grains of a substantially uniform crystallographic surface orientation on a substrate, irradiating the film using a pulsed light source to provide pulsed melting of the film under conditions to provide a plurality of liquid sections and solid sections extending throughout the thickness of the film, creating a mixed liquid/solid phase having a periodicity of less than the solid-liquid coexistence length (λₗₛ) and comprising one or more of the seed grains, allowing the mixed solid/liquid phase to solidify from the seed grains under conditions that provide a textured polycrystalline layer having the selected surface orientation and irradiating the film using a second pulsed light source to provide pulsed melting of the film under conditions that provide a plurality of solid sections and liquid sections extending throughout the thickness of the film, creating a mixed liquid/solid phase having a periodicity of greater than formed in the first pulse, and allowing the mixed solid/liquid phase to solidify under conditions that provide a textured polycrystalline layer having the selected surface orientation, wherein at least one of the surface texture, grain size, and defectivity is improved in the second pulsed irradiation.

In one or more embodiments, at least one grain remains in the film after the first pulsed irradiation that is different from the selected surface orientation, and wherein the number of said different grains is reduced in the film after the second irradiation pulse.

In one or more embodiments, the first and second pulsed light sources are divergent light sources.

In another aspect of the invention, a method of forming a solar cell is provided including (a) providing a textured seed layer by providing a silicon film comprising seed grains of a {100} surface orientation on a substrate; irradiating the film using a pulsed divergent light source to provide pulsed melting of the film under conditions that provide a pluarality of solid sections and liquid sections extending throughout the thickness of the film , creating mixed liquid/solid phase having a critical solid-liquid coexistence length (λₗₛ); and allowing the mixed solid/liquid phase to solidify under conditions that provide a textured polycrystalline layer having the selected surface orientation; and (b) epitaxially growing a polycrystalline silicon layer on the textured seed layer to form a textured film.

In another aspect of the invention, a textured polycrystalline film is provided having at least 90% of the surface area of the film oriented to within about 15° of the {100} pole.

The disclosed techniques, for example, can control the heating cycle experienced by any location in the film. The described methods and system can be used for creating seed layers in an epitaxial growth process for making solar cells. These methods and systems can enable the use of FLA and other low cost divergent light sources, such as diode laser, for large scale production of crystalline films for solar cells. The process may further be used to create (100) textured films for use in 3D-ICs.

### BRIEF DESCRIPTION OF THE DRAWINGS

The disclosed subject matter is described with reference to the following drawings which are presented for the purpose of illustration only and are not intended to be limiting of what is disclosed herein.

FIG. 1 is a schematic illustration of a flash lamp apparatus that may be used, according to some embodiments of the disclosed subject matter.

FIG. 2 is a cross-sectional illustration of a (A) melt profile and corresponding temperature profile of a film having homogeneous crystal morphology and (B) the resultant solidified film, according to some embodiments of the disclosed subject matter.

FIG. 2C is a graphical representation of a critical solid-liquid coexistence length (λₗₛ) of a mixed solid/liquid phase film, according to some embodiments of the disclosed subject matter.

FIG. 3 is a cross-sectional illustration of (A) a film having heterogeneous crystal morphology; and (B) a melt profile and corresponding temperature profile of the heterogeneous film, according to some embodiments of the disclosed subject matter.

FIG. 4 is a cross-sectional illustration of (A) a film having a heterogeneous crystal morphology, (B) a melt profile and corresponding temperature profile in which the periodicity commensurate with λₗₛ is less than the spacing between (100) grains so that some (hkl) grains survive; and (C) the resultant solidified film, according to some embodiments of the disclosed subject matter.

FIG. 5 is a plot of grain size vs. number of exposures, illustrating the effect of multiple exposures on grain size, according to some embodiments of the disclosed subject matter.

FIG. 6 is a plot of % (100) texture vs. number of exposures, illustrating the effect of multiple exposures on texture size, according to some embodiments of the disclosed subject matter.

FIGS. 7A and 7B are photomicrographs of an Si thin film that has been crystallized using partial melt processing and continuous wave complete melting, respectively, according to some embodiments of the disclosed subject matter.

FIGS. 8A and 8B are schematics of a thin film crystallization system implementing heat flow isolation, according to some embodiments of the disclosed subject matter.

### DETAILED DESCRIPTION

This application provides methods and systems to produce high efficiency and low cost silicon thin films that are suitable for use in solar cells. The application uses flash lamp technology or other low cost pulsed flood light source, such as a diode laser, to provide pulsed melting of a silicon film under conditions that provide a mixed liquid/solid phase. The solid phase provides seeding sites for the crystalline growth of silicon from the liquid phase. Under appropriate conditions, a highly textured poly-Si layer is obtained. In one or more embodiments, a poly-Si layer with strong (100) texture is provided. The present application also uses flash lamp annealing for creating seed layers in an epitaxial growth process for making solar cells. It will be apparent from the description that follows that the method is not limited to silicon thin film crystallization and may be practiced for any thin film that shows an increase in reflectivity upon melting. For the purposes of discussion that follows, unless specifically noted, the methods may be used for any such material. It also will be apparent from the description that follows that other pulsed light sources may be used, so long as they also provide a pulsed divergent light source or a pulsed flood light and the desired control of the mixed phase partial melting process. Unless explicitly stated, flash lamp annealing or “FLA” is also meant to include diode lasers and other divergent pulsed light sources used as a “flash lamp.” Glass compatibility may be very challenging with FLA, thus other substrates are also considered for use in this process.

Partial melting zone melt recrystallization can be used to provide crystalline films having (100) texture under favorable conditions. In a conventional ZMR process, growth of the long (100) textured grains starts on grains formed in the “transition region” between the unmelted and the completely melted areas of the film. This is the regime of partial melting in which regions that are either solid or liquid throughout the thickness of the film co-exist, and that only exists in radiatively heated Si films as a result of a significant increase in reflectivity of Si upon melting (a semiconductor-metal transition). In this partial melting regime, {100} surface-oriented grains have been observed to dominate, a phenomenon that is sometimes linked to a crystallographic anisotropy in the Si0₂—Si interfacial energy. As a result of the negative feedback that results from the reduction in heat coupling to the film from increased melting, the partial melting regime is self stabilized and can be induced throughout the film by radiation at beam intensities below what is required for complete melting. This has been demonstrated in a partial melting ZMR process using continuous wave laser scanning See, e.g., van der Wilt, et al., “Mixed-Phase Zone-Melting Recrystallization of Thin Si Films Via CW-Laser Scanning,” Materials Science and Engineering, Columbia University, March 2008, which is incorporated by reference.

One limitation of the laser based ZMR processes is that the light from lasers suffers from coherence, which makes it challenging to create well-homogenized beams. Variation in the power will lead to variation in the solid to liquid ratio in the mixed phase and in a variation in the effectiveness of the process. The non-uniformity in a line-beam created using a diffractive optical element (DOE) can be as large as +/−15%. The melted zone is often very narrow so that heat diffuses sideways through the film, which then requires higher light intensity to compensate for heat loss. However, this also gives rise to smaller grains. Another limitation of the technique is the cost associated with the laser technology. For most practical applications, a single laser head is not powerful enough (up to e.g., 18W) and multiple heads need to be integrated to create a sufficiently large and sufficiently powerful beam. This will further add to system complexity and cost. Finally, most lasers are also known to be inefficient sources of light in which much power is used to create an often monochromatic source of light.

Further, irradiation using a line-beam shaped pulse laser source and a pulsed flood light source (i.e., using FLA) create different surface morphologies in the thin film. Normally upon lateral growth (e.g., with SLS), the lateral growth fronts collide and a protrusion is formed. Such protrusions can be considered problematic for at least certain applications. Such protrusions also can be formed with FLA. With scanning mixed phase solidification (MPS), as discussed below, those protrusions generally are not formed. Instead, the resultant film has one or more droplets in on top of the resultant film. These droplets can be many times the film thickness (e.g., four or more), while protrusions are typically less (e.g., four or less). The droplets form because the excess liquid formed by the scanning is not trapped in between two growth fronts, but rather is transported along with the scanning beam through the liquid channels that exist in between the growing crystals. Although pulsed MPS films are not entirely smooth, a pulsed MPS does not have the droplet formation of scanned MPS films.

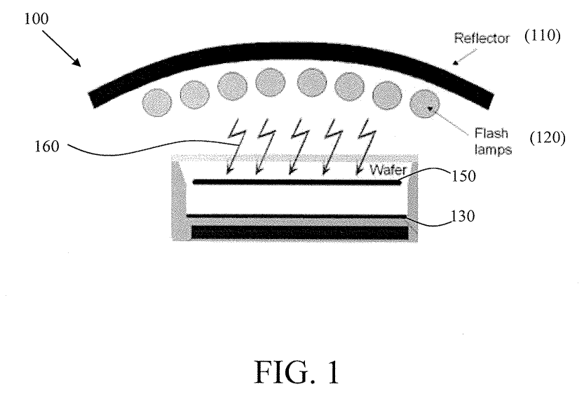

Flash laser annealing uses a flash lamp to produce white light over a wide wavelength range, e.g., 400-800 nm. The flash lamp is a gas-filled discharging lamp that produces intense, incoherent full-spectrum white light for very short durations. A flash lamp annealing apparatus uses white light energy for surface irradiation, in which the light is focused using, for example, an elliptical reflector to direct the light energy onto a substrate, such as is shown in FIG. 1. FIG. 1 is a simplified side view diagram representing a flash lamp reactor 100 with a reflecting device 110, in accordance with an embodiment of the present invention. The flash lamp reactor may include an array of flash lamps 120 located above a support 130, with a target area 150 situated between the two. The reflecting device 110 may be positioned above the flash lamps to reflect varying amount of radiation 160 from the flash lamps back towards different portions of a facing side of the target area. The target area may be adapted to receive a substrate (wafer).

The lamp power is supplied by a series of capacitors and inductors (not shown) that allow the formation of well defined flash pulses on a microsecond to millisecond scale. In a typical flash lamp, light energy densities in the range of up to 3-5 J/cm² (for a 50 μs discharge) or 50-60 J/cm² for a 1-20 ms discharge can be obtained. In exemplary embodiments, the light energy density can be about 2-150 J/cm². Flash lamp annealing allows fast heating of solid surfaces with a single light flash between some tens microseconds and some tens milliseconds, e.g., 10 μs-100 ms. Variables of the flash lamp that affect the quality of thin film crystallization include the energy intensity of the incident light, as well as the pulse duration and shape of the light (which results in a certain dwell time, i.e., a duration of melting).

Because flash lamp irradiation is a flood irradiation process, the flash lamps can irradiate large areas of the substrate surface in a single pulse. It is possible that the entire film on a substrate, for example, a glass panel, can processed simultaneously. Thus, multi-pulse operations in a scanned fashion to cover a large substrate area, for example, as used in laser-based recrystallization, are not required. However, the flash lamp irradiation is not limited to full substrate irradiation, and the flash lamp may also be shaped in a limited area, e.g., a line beam to irradiate a selected region of the film. In one or more embodiments, the substrate and flash lamp apparatus optionally can be arranged so that the surface of the film is scanned and sequentially exposed to light energy from the flash lamp apparatus. Exposures may be overlapping to ensure complete crystallization of the film. Exposures may further be overlapping by a large degree to create multiple radiations per unit area while scanning.

Under certain irradiation conditions, liquid phases and solid phases can coexist in the silicon film, and the solidification process based on that melting regime is referred to as “mixed phase solidification” or “MPS.” In one or more embodiments, irradiation using a flash lamp, diode laser in divergent mode or other pulsed flood or divergent light source is carried out under conditions to provide mixed solid and liquid phases. These regions are solid or liquid throughout the thickness of the film, although the overall irradiated surface includes regions of solid and regions of liquid. The liquid phase may occupy larger volume fractions than the solid phase. The solid phase serves as seeding sites for formation of crystalline domains during solidification and commonly growth of large <100> textured grains is observed. In the MPS process, a near equilibrium is established between the dynamically coexisting solid and liquid phases. The balance between solid and liquid phases is used to control the different characteristics of the crystalline grains created after solidification. These characteristics include grain size and grain orientation, specifically in the {100} surface direction, and defect density.

In MPS, the film is partially molten in a way that is found to favor {100} surface oriented grain growth at the expense of other orientations which may disappear during the melting or, when not eliminated during the mixed phase melting, which may undergo less growth than the <100> grains during cooling and solidification. Such orientation-dependent anisotropies in melting and growth occur under close-to equilibrium conditions. Mixed phase melting is established as a result of the difference in reflectivity, R, between solid and liquid Si for wavelengths roughly in the visible spectrum. Liquid Si has a higher reflectivity than solid Si and tends to reflect incident light. Provided the non-reflected light is sufficiently absorbed, the difference in reflection results in solid regions being heated more than liquid regions. This negative ΔQ (Q is the heat generated in the film, ΔQ=Q(liquid)−Q(solid)) results in a material in which liquids and solids are in a dynamic balance wherein liquids are undercooled and solids are overheated.

In one or more embodiments, flash lamp annealing conditions are controlled to provide a liquid content in the mixed phase material that is greater than about 50 vol % liquid. The liquid phase can approach 100 vol %, but complete melting of the entire film should be avoided. In one or more embodiments, the liquid phase is about 50 vol % to less than about 100 vol %, or about 80 vol % to about less than 100 vol %, of the mixed liquid/solid phase during flash lamp irradiation.

<100> textured films are obtained through MPS provided that {100} surface-oriented seeds are present prior to establishing the mixed phase melting of the film. As used herein, “{100} surface oriented grains or {100} seeds” means grains/seeds having substantial {100} surface orientation, for example, within 5, 10, 15, or 20 degrees of the {100} pole. Thus, in one or more embodiments, the film is pretreated to provide {100} surface oriented grains or {100} seeds. Seeds may be created either during deposition, if the precursor film is poly-crystalline; or, if the precursor is amorphous, during post-deposition treatments (e.g., pulsed laser crystallization or solid phase crystallization) or in the early stages of the crystallization process to induce MPS (i.e., preceding the establishment of the mixed phase), for example, via solid phase crystallization or via melt-mediated explosive crystallization. The {100} seed content of the precursor film affects the degree of melting as well as the dwell time that is required to achieve strongly <100> textured films. For randomly textured films, a large degree of melting and/or a longer dwell time is required to achieve strong texture. For {100} surface textured precursor films (e.g., available via certain CVD processes), a lower extent of melting may be sufficient. See, U.S. Ser. No. 10/994205, entitled “Systems and Methods for Creating Crystallographic-Orientation Controlled Poly-Silicon Films,” which is hereby incorporated in its entirety by reference.

In order to achieve improvements in grain size and grain texture, at least some melting of the film should occur. If the energy density of the flash lamp irradiation is too low, no melting will occur (at a certain dwell time) and the resultant film will have small grain size and show little to no improvement in texture. If less than 50 vol % liquid phase is achieved, then the mixed phase is rich in solid phase seeding sites, but there is insufficient melting to remove all non-{100} surface oriented grains or to provide a significant increase in crystal growth. As the volume percent liquid phase increases, a larger number of grains will fully melt so that the grain size of the re-crystallized grains will increase accordingly. However, if melting in the irradiated region is complete, e.g., 100%, large poly-Si grains will form as the grains grow laterally from the unmelted solids located at or near the edge of the irradiated regions. In addition, highly defective grains may form when the liquid is allowed to become significantly supercooled (i.e., in the absence of laterally growing grains) so that it solidifies via nucleation of solids. While large polycrystalline grains may be formed from the complete melt, the laterally grown regions are commonly highly defective and exhibit poor-to-no preferred grain orientation. Although not found in all instances, it is frequently the case that re-crystallized films formed from a mixed liquid/solid phase contain polycrystalline grains that are smaller in size, but of lower defect density and greater texture, than those formed from a complete melt recrystallization. In one or more embodiments, the resultant film includes greater than about 90% of the surface area of the film having an {100} surface orientation of within about 15° of the {100} pole. In other embodiments the surface orientation is within about 10°, or about 5° of the {100} pole.

Multiple factors are considered when optimizing the resulting seed layer. The dynamic balance of liquid and solid during flash lamp irradiation can be maintained by control of the lamp and beam properties and/or the irradiation conditions. The light intensity (energy density), temporal profile of the light exposure (pulse shape and dwell time) and light wavelength range can be controlled. During flash lamp irradiation, processing conditions such as the arrangement of the lamp (focus, etc.), the equipment and irradiation implementation conditions, the scan conditions, scan number, exposure number, substrate heating, film preheating, co-irradiation and variable intensity exposure can be controlled to obtain the desired melting and solidifying conditions.

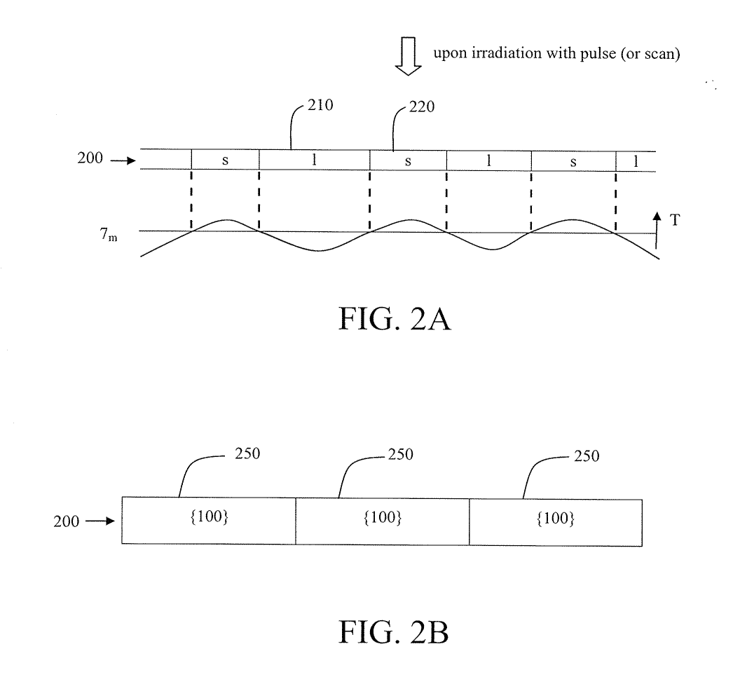

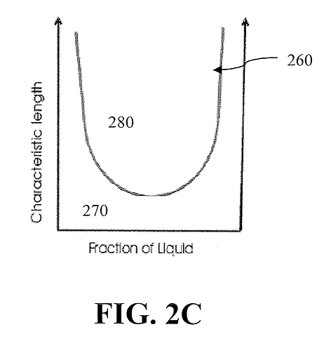

FIG. 2A is a cross-sectional illustration of the liquid 210 and solid 220 phases that can be generated in a film 200 of homogeneous crystallinity or under steady state irradiation conditions. Homogeneous crystallinity means that the crystals arising from the liquid and solid regions have uniform orientation (for example (100)) in the film 200 and contain few or no defects. The liquid 210 and solid 220 regions are fairly regularly spaced and the solid regions 220 are fairly uniform in size (as are the liquid regions 210). As shown in FIG. 2B upon crystallization of the liquid regions, the film 200 contains a higher proportion of grains 250 having {100} surface orientation. The dimension of the liquid phase can approach the critical solid-liquid coexistence length (λₗₛ), which is the extent to which two phases can exist before the mixed phase becomes unstable.

However, the critical solid-liquid coexistence length (λₗₛ) is not a fixed length. Rather, it depends on details of the irradiation and the sample configuration (i.e., film thickness, thermal conductivity of film and substrate, which influences heat removal) and the fraction of liquid in the film. A graphical representation of λₗₛ 260 is shown in FIG. 2C. The x-axis of FIG. 2C is fraction of liquid, i.e., how much liquid is in the film. The y-axis is the solid-liquid coexistence length (λₗₛ). The area above the curve 260 is the unstable region 270. That is, the mixed solid liquid phase cannot exist at those coexistence length and liquid fraction values. The area below the curve 260 is the stable liquid solid coexistence region 280. Values of the coexistence length and liquid fraction in the stable liquid solid coexistence region 280 create a stable mixed solid/liquid phase. Therefore, values of coexistence length and liquid fraction can approach and equal the critical solid-liquid coexistence length (λₗₛ) , but should not exceed it, without the mixed solid/liquid phase becoming unstable. Preferably, the mixed solid/liquid phase should be at or near the critical solid-liquid coexistence length (λₗₛ).

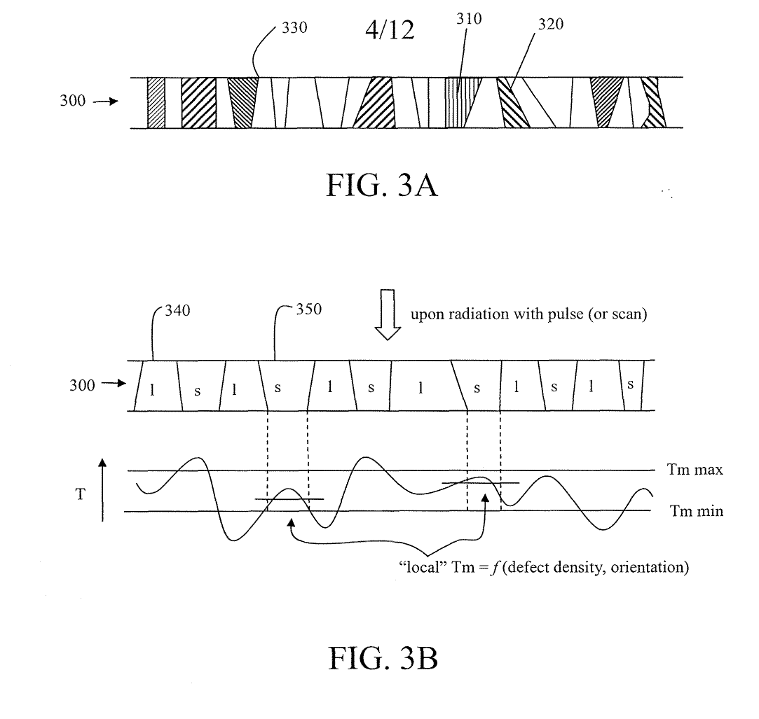

Further, the value of the solid-liquid coexistence length can vary based on the grain size of the thin film. For example, as shown in FIG. 2A, films with large grains generally have a large solid-liquid coexistence length. However, as shown in FIG. 3A, films with small grains generally have small a solid-liquid coexistence length.

In certain embodiments, the microstructure of a precursor film allows the liquid/solid periodicity to reach a value commensurate with this critical dimension. Going beyond that critical dimension is not possible, but it is possible to select a process that approaches or reaches λₗₛ. For mixed phase systems with more than ˜50% liquid, a further increase in the liquid fraction of the mixed phase system leads to longer λₗₛ, as is discussed in greater detail below. When the mixed phase becomes unstable (i.e., an unsustainable degree of superheating in the solids and/or of supercooling in the liquids), that situation typically will be rectified through melting or growth to create liquid or solid regions within those unsustainably superheated or supercooled regions, respectively, and regain near equilibrium conditions. The growth of solids in this case does not occur through nucleation as the degree of supercooling is insufficient. Such an arrangement can also arise in a material that is in a steady state irradiation, that is, in a material in which liquids and solids are in a dynamic balance wherein liquids are undercooled and solids are overheated.

FIG. 3A is a cross-sectional illustration of a heterogeneous film 300 containing multiple grain boundaries 330 and grains 310, 320 of different orientations. The grains can also have different levels of defectiveness. The melting of such a heterogeneous film is influenced by preferred melting of grain boundaries, as well as differences in melting behavior of the grains depending on their crystallographic orientation and their defectiveness. The film will form liquid 340 and solid 350 regions that are of varied spacing from one another and of varying size, as is illustrated in FIG. 3B. In addition, once a mixed phase is established, the complete melting condition, or temperature, of a particular grain is affected by the total fraction of solid within the heat diffusion length of that grain, as well as to a curvature effect leading to a higher melting temperature (Gibbs-Thomson effect). The different grains in the heterogeneous film will thus have different local melting temperatures (Tₘ) that are a function of defectivity density and orientation. Under uniform irradiation the film will have a range of Tₘ (Tₘₐₛ-Tₘₘ)and there will be a slight but significant variation in the temperatures of the liquid and solid regions, as is illustrated in FIG. 3B. It is found that {100} surface oriented grains are most resistant to melting, but other orientations, especially in the absence of {100} grains nearby, may survive as well. When initially heating and melting a heterogeneous film, the periodicity and size uniformity of the liquid and solid regions may be compromised and the dimensions will be smaller and will be related to nature of the precursor film. Thus, the ability to readily form large domains of liquid depends in part on the quality of the film. The solid-liquid periodicity might, at least initially, be less than that for a homogeneous film. Heterogeneous films may require longer dwell times and/or multiple exposures to reach a mixed phase having dimensions correlated to kᵢₛ.

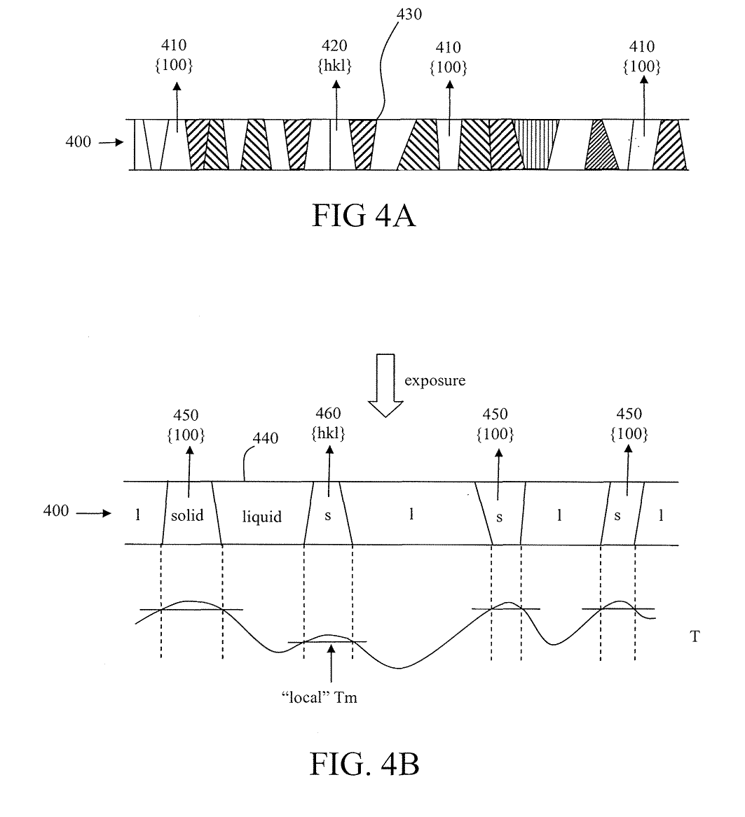

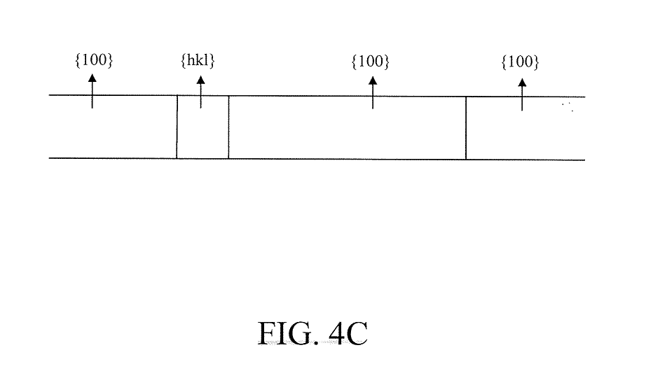

FIG. 4A illustrates the effect of a heterogeneous film 400 with low levels of grains 410 of the stable {100} surface orientation and thereby high levels of grains of a different orientation, e.g. surface oriented {hkl} grains 420, on the formation of mixed phase regions. FIG. 4A is a cross-sectional illustration of a heterogeneous film containing multiple grain boundaries 430 and grains 410, 420 of different orientations. In this case, there is a spacing between (100) oriented grains that is greater than the critical solid-liquid coexistence length (λₗₛ). Upon irradiation, the film will form liquid 440 and solid 450, 460 regions that are of varied spacing from one another and of varying size, as is illustrated in FIG. 4B. In addition, solid regions 450 and 460 can have different crystallographic orientations. The critical solid-liquid coexistence length is insufficient to form liquid regions bridging (100) seeds and that that is why the {hkl} grain can survive, as shown in FIG. 4C.

Seed crystals 420 having an undesired orientation may be very difficult to remove when λₗₛ is short. Thus, when using a heterogeneous film, even when a solid liquid periodicity commensurate to critical solid-liquid coexistence length can be achieved, this may not guarantee obtaining a highly textured film, because the spacing between {100} oriented grains may be larger than the critical solid-liquid coexistence length (or, stated differently, the critical solid-liquid coexistence length is too short).

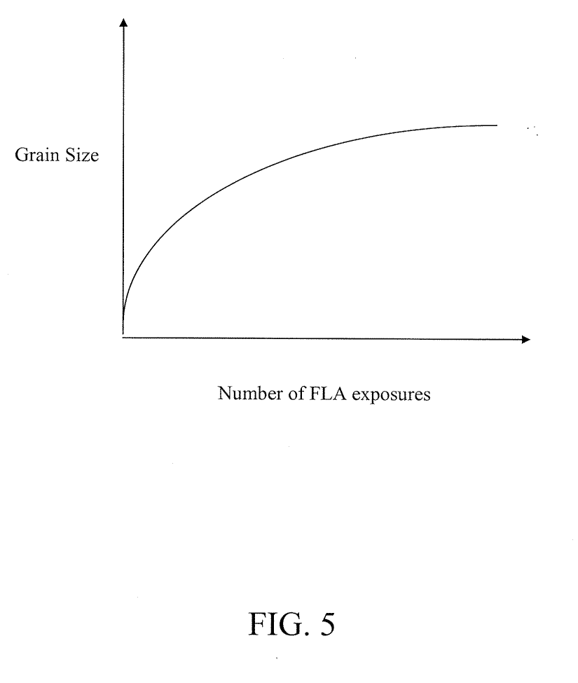

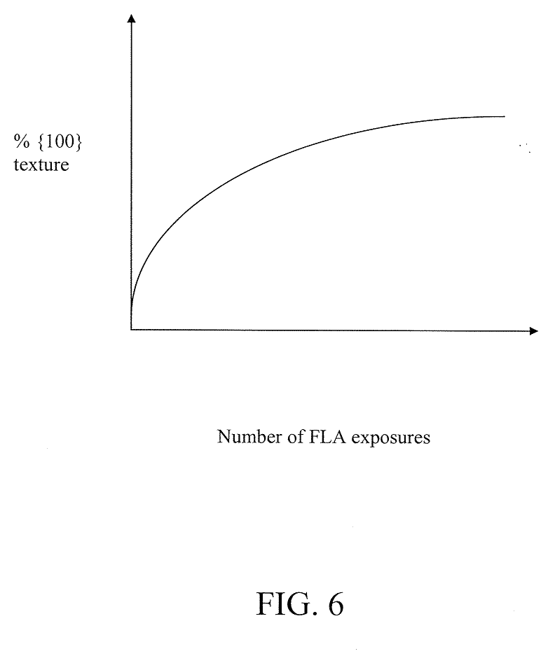

In one or more embodiments, the film is subjected to multiple FLA exposures. In some embodiments, the film surface may be exposed twice or multiple times up to about one hundred or more or a few tens times, and more typically is exposed about 2-10 times, or 2-4 times. As crystallographic texture is achieved over multiple exposures, the annealing conditions can be selected to produce a mixed phase composition that has a lower liquid content. Thus, the flash lamp can be operated with lower intensity and/or with shorter dwell times. Such conditions could be compatible with thermally sensitive glass substrates. Multiple exposures can have the advantage of resulting in larger-grained and more strongly textured films. The improvement in average grain size with increasing number of scans is illustrated pictorially in FIGS. 4C and 5. Similarly, the anticipated increase in the level of (100) texture (depicted at % {100}) is shown in FIG. 6. Thus, multi-exposure processes tend to produce higher quality films.

In a first exposure, the solid liquid periodicity may not yet reach a value dictated by λₗₛ. This could be the result of the heterogeneity of the precursor film in which defective grains or regions, including grain boundaries, or even grains with certain orientations, may melt preferentially over low-defect-density grains or regions and/or {100} surface oriented grains. See, FIGS. 4A-4C. Thus, while some improvement in the grain orientation and defectivity is observed in a single irradiation process, inherent heterogeneity in the starting film does not give rise to large periodic liquid and solid regions. Subsequent irradiation of the marginally improved sample will provide a film of increased {100} surface orientation and reduced defectivity. The solid/liquid periodicity also may not yet reach a value dictated by λₗₛ if the initial microstructure of the precursor film is on a scale much smaller than λₗₛ. In such circumstances, a mixed phase is created with a periodicity on the same scale as the microstructure, as it generally takes time for the mixed phase to evolve. This will be particularly the case in situations where a short dwell time is preferred (e.g., for substrate compatibility) and in those cases a multiple pulse process may be used to sequentially increase the grain size and the texture of the films. The resultant films have a high level of (100) grains and the grain size is generally larger than that achieved with single exposure.

Depending on the application, a single exposure technique may be sufficient. Because single exposure techniques require approaching complete melt conditions, the multi-exposure techniques afford more freedom and the factors can be adjusted within a wider window of operation. In fact, the difference in degree of melting desired in a single-pulse or a multiple pulse process may not be all that large. While a lower degree of melting may be possible (e.g., 90 to 95% instead of 99% or approaching 100%) in multiple exposure methods, the real gain from multiple exposures is the gradual elimination of the non-(100) grains while also increasing the liquid/solid periodicity. Also, subsequent radiations need not be at the same energy density, for example, the energy densities may be different to accommodate changes in the optical properties of the film (e.g., due to phase change or change in defect density), or to optimize the sequential increase in grain size and texture.

For example, experimental observation has shown that the second and subsequent pulses in a multiple pulse process, starting with an amorphous or highly defective precursor, can actually have an energy density as much as twice that of the first irradiation pulses. This is related to the use of longer wavelength light at which transparency shifts between amorphous and crystalline are much larger. Therefore, the second and/or subsequent pulses may need significantly higher energy, e.g., twice, or at least more than 20% more energy than the first pulses. This difference is much larger than previously observed during work on scanning-mode MPS where shifts on the order of a few percent, but no more than 20% were used.

In one or more embodiments, a thin seed layer thin film is exposed to multiple exposures in a pulsed flood or divergent irradiation process to not only reach grain sizes commensurate with λₗₛ, but also to clean up the material and remove non-(100) grains. As is described herein, a single exposure may lead to small non-(100) grains located at or near grain boundaries. See, FIGS. 4A-4C. While for some applications/situations this may be acceptable, it is not the most optimal. These grains are very hard to remove without resorting to multiple exposures. This may be due the use of a heterogeneous precursor where a solid-liquid ratio may be established based on the small grain size and large spacing between (100) seeds and a non-(100) seed, which may survive simply because the distance between the (100) seeds exceeds λₗₛ even permitting time for establishing a periodicity commensurate to λₗₛ, even when there is time for establishing a periodicity commensurate with λₗₛ (long dwell time).

In another embodiment, a second FLA pulse can be spaced close enough to the first FLA pulse in the time domain that the film is still at elevated temperature from the first radiation, although it could be substantially solidified, when it is hit with the second radiation. Thus, the reduced energy requirements for the second pulse due to the residual temperature may lead to larger λₗₛ. In this embodiment, there may be a need for two (arrays of) flash lamps to allow pulses closely following each other.

During FLA, the discharge lamps can provide light energy as a discharge current pulse, wherein the pulse full width at half maximum (FWHM) can range from less than tens of microseconds to more than tens of milliseconds. For multiple irradiations, the frequency of the pulses can also be controlled and typically can vary in the range of hundreds of hertz. Dwell time is the time from the onset of melting to full solidification. In continuous waveform (CW) techniques, the dwell time is largely influenced by the spatial profile of the laser beam and may further be influenced by heat diffusion away from the scanned laser. In FLA techniques or other flood or divergent irradiation techniques, the dwell time is mostly influenced by the temporal profile of the flash lamp. Also, dwell time may be influenced by various means of preheating.

As the dwell time is increased, the texturing process may be more pronounced, but the substrate is also exposed to light energy for a longer duration. The thermal diffusion coefficient transports the heat through the film thickness. Longer dwell times, while improving the quality of the grain size and texture of the seed layer, may cause heat to undesirably transport into the substrate, which is problematic for heat sensitive substrates.

A further feature of the flash lamp is the light energy density of the incident light, which depends on the input energy of the flash lamp, can be controlled by varying the voltage and capacitance of the flash lamp. Light energy density will vary with the particular flash lamp apparatus that is used (e.g., pulse duration and pre-heating), but can typically vary in the range of less than about 2 to 150 J/cm² or more. The energy intensity is desirably above a threshold level I₁ in order for melting and mixed phase recrystallization to occur. Below the energy threshold I₁, the film does not form any liquid phase and improvements to grain size and texture are poor, even at long dwell times. The light intensity is also desirably below an upper intensity I₂, at which the film melts completely. At high energy intensities, I₂, the exposed area will melt completely and the benefits of mixed phase recrystallization are not observed.

Another factor in controlling the beam quality is related to the wavelength range of the incident white light. As noted above, mixed phase melting is established as a result of the difference in reflection between solid and liquid for wavelengths roughly in the visible spectrum. The liquid phase exhibits higher reflectivity. Provided the non-reflected light is sufficiently absorbed, the difference in reflection results in solid regions being heated more than liquid regions, which is a necessary condition for the mixed phase melting and solidification to occur.

Different light sources will have their own unique wavelength range which will be absorbed by the film. Commonly used light sources in Si film crystallization radiate at short wavelengths, for example, UV light from excimer lasers (e.g., 308 nm for XeCI) or medium wavelengths, for example, frequency doubled diode-pumped solid state lasers (e.g., Nd:YVO4 at 532 nm). These wavelengths absorb entirely (for UV) or sufficiently well (for green 532 nm) in Si. Longer wavelengths may not absorb well enough and are not efficient for crystallizing thin Si films (for optical data on absorption in Si, see for example the 88^{th} edition (2007-2008) of the CRC Handbook of Chemistry and Physics, section 12, p 12-1 38, which is incorporated herewith by reference). The light from flash lamps also contains much longer wavelengths (a Xe gas discharge lamp produces white light in the range of 400-800 nm) and the light of diode lasers may be exclusively consist of long wavelengths (e.g., ˜808 nm). An appropriate mixed phase can for instance be achieved using 532 nm light. Even so, at this wavelength, the Si film may already be partially transparent (depending on film thickness and interference effects) and some thicknesses are better suited than others for inducing MPS.

As a result of these transmission losses (which are expected to be higher for the semiconducting solid Si than for the metallic liquid Si), for longer wavelengths it will become progressively more difficult to get a sufficiently negative ΔQ to induce MPS, even though the change in reflectivity ΔR is still positive (ΔR=R(liquid)−R(solid)). In one or more embodiments, a metallic layer is used underneath the Si layer as a heat absorption layer. The heat of the incident light that is not absorbed by the Si layer is absorbed instead by the underlying metal layer and thermally diffuses back into the Si layer. The metal layer can be any metal having the appropriate thermal absorption. By way of example, the metal layer can include a molybdenum film deposited prior to Si deposition (with a possible barrier in between) or it could be a metallic substrate (e.g., a flexible stainless steal substrate for making flexible large area electronics such as solar cells or AM-OLEDs). In one or more embodiment, the metal does not negatively interact with the Si layer, for example, by poisoning the layer. In other embodiments, a barrier layer is disposed between the metal layer and the Si substrate. In one or more embodiments, a metal film is provided only in selected areas (e.g., using lithographic processes) so that MPS can be induced in those selected areas only while in other areas less light gets absorbed resulting is less heating.

In one or more embodiments, other efficient pulsed light sources may be used for the MPS process. One such example is a diode laser, which is capable of pulsed lasing at for example ˜800 nm and which has been previously been used to induce melting in a process referred to as diode laser thermal annealing. See, e.g., Arai, et al., “41.2: Micro Silicon Technology for Active Matrix OLED Display,” SID 07 Digest, pp. 1370-1373 (2007) and Morosawa, et al., “Stacked Source and Drain Structure for Micro Silicon TFT for Large Size OLED Display”, IDW, pp. 71-74 (2007), which are incorporated herein by reference in their entirety. High power diode lasers can be power efficient and can have high divergence, making them more lamp-like than most other lasers. Their divergence makes them more suitable than other lasers to be placed in arrays to establish uniform 2-D heating of a film. Diode lasers can also be pulsed and the short pulse durations that can be achieved may be beneficial for reaching compatibility with low-cost substrates, such as glass. A metal layer underlying the silicon film may be required in order to sufficiently absorb the light of a diode laser due to the longer wavelength of light and to successfully establish mixed phase melting and solidification. In one or more embodiments, a metal layer may be used even with wave-lengths of light that absorb well, in order to achieve desired heating effects. The metal layer may further be useful to smear out non-uniformities in the radiation from the diode laser as can for example result from the coherence of the light. The metal layer is very conductive and may redistribute heat from hot spots to cooler regions nearby on a time scale shorter than, or comparable to, the time required to establish a mixed phase. The metal layer may also be patterned to induce MPS only in desired areas.

In the mixed phase melting and solidification regime, a critical solid-liquid coexistence length (λₗₛ) can be recognized beyond which the mixed phase becomes unstable as a result of the degree of superheating and undercooling of the solids and liquids respectively reaching unsustainably high values. As a result, the mixed phase will evolve into an approximately periodic structure consisting of superheated solid regions alternating with undercooled liquid regions. See, FIG. 4. The periodicity is linked with λₗₛ, which in turn will be determined based on the details of radiation, pre-heating, and heat flow in the film, as well as the degree of melting established; a simple analysis has been provided previously in Jackson, et al. “Instability in Radiatively Melted Silicon Films,” Journal of Crystal Growth 71, 1985, pp. 385-390, the contents of which are incorporated in their entirety by reference. As growth proceeds from the solid regions into the liquid regions, it follows that the grain size will generally tend to saturate at values around λₗₛ. As there is a dependence of λₗₛ on the liquid fraction, larger grains can be obtained by radiation at a condition close to complete melting, e.g., under condition of large liquid content.

In situations where the crystallinity of the seed layer is not homogeneous, e.g., there is a variation in the orientation and defectivity of the grains, the mixed phase periodicity of liquid and solid may not be uniform. In addition, the liquid regions may be smaller than λₗₛ due to the presence of preferentially melting grain boundaries that interrupt the optimal formation of the liquid phase. In one or more embodiments, the flash lamp irradiation process is selected to increase λₗₛ, increase grain size and reduce defectivity.

Various techniques can be used to increase the coexistence length so as to approach λₗₛ. One technique involves lowering the intensity of the incident light. The intensity of radiation can be reduced by reducing the rate of loss of heat towards the substrate or the surroundings. In one embodiment, by using flood pulsed annealing of a large section of the film, there are no significant lateral temperature gradients and less intense radiation suffices to establish MPS. In further embodiments, lower intensity radiation may be established by sample pre-heating, e.g., via co-irradiation from front or back side or via hot-plate heating, or by increasing the pulse duration. Further, the use of pulsed MPS as opposed to line-scanned MPS reduces the lateral heat loss and thereby increases λₗₛ.

The temporal profile of the beam also may be controlled to improve the degree of (100) texture. Even when a light irradiation technique achieves co-existence of solid and liquid phase, it may not result in a desired quality of crystalline growth. Growth may take place at a condition progressively further removed from equilibrium and the growth may be more defective due to defect formation and orientation roll off. Thus, a factor in increasing the quality of {100} surface-oriented grains in the film is controlling the speed of ramping down the pulses. In “beam off” crystal growth, the energy density changes (decreases) abruptly and cooling and crystallization takes place in the dark, e.g., with the light beam off Beam-off crystal growth can have a strongly facetted nature, but may also quickly result in loss of orientation through twinning, defective growth, and/or orientation roll off. So, even though the mixed phase formed during irradiation may predominate a material having a {100} surface orientation, once it cools down the orientation may not be preserved.

In one or more embodiments, the {100} surface orientation is obtained using a “beam on” temporal energy profile. In “beam-on” crystal growth, radiation of the film (albeit at decreasing intensity) is continued after mixed phase formation. The near-equilibrium condition is maintained longer during the solidification and the quality thereof is higher as well as having stronger preferential growth of {100} surface oriented seeds over other orientations. In beam-on solidification, the growth of solid seeds may itself become subject to the mechanisms that result in the formation of the mixed phase and, as a result, the growth front may not be facetted but may become cellular or even dendritic in nature to maintain a solid-liquid periodicity commensurate with λₗₛ. The periodicity of the cellular growth front will further be affected by the reduction in λₗₛ as the liquid content decreases. Such modes of growth need not result in defective material but ultimately are characteristic of material having typically at least low-angle grain boundaries. Considerations of beam-on and beam-off solidification scenarios lead to an engineered temporal beam profile that may establish a trade-off between the extreme scenarios experienced in either, as well as in the maximum extent of melting that is induced.

Exemplary suitable beam-on conditions may be determined empirically or by using crystallization modeling. In one embodiment, a Si thin film is irradiated at a peak power to produce a large volume fraction of liquid, i.e., near complete melt. After that, for beam-on radiation, the light power is gradually reduced until complete solidification has occurred. The complete solidification time depends on growth velocity. Growth velocities in silicon can be up to more than 10 m/s as for example encountered in pulsed-laser induced lateral growth using excimer lasers with 10s or 100s of nanosecond pulse duration. For the present method, longer pulse durations are envisioned and velocities may be more on the order of 1 cm/s to 1 m/s. Then, assuming growth distances of 1 or up to 5 or 10 μm (depending on solid-liquid periodicity), this would mean a gradual ramp down of 1 μs to 1 ms. In general, before substantial solidification has occurred, the power is lowered to between 40% and 90% or between 60% and 80% of the peak power of the flash lamps. Hawkins and Biegeleson (Appl. Phys. Lett., 42(4), February, 1982 pp. 358-360) which is incorporated in its entirety by reference, show the relationship between silicon temperature and laser power and indicate a plateau at which liquid/solid mixed phases coexist.

Without being bound by any particular theory or mode of operation, one reason why the growth in beam-on crystallization is believed to have a low defect density is related to the temperature gradients in the film. In pulsed laser crystallization, e.g., directional sequential lateral solidification, there are typically very strong temperature gradients in the region behind the growth interface. These result in temperature-gradient induced stresses which are believed to be the source of defect formation through plastic deformation; especially of low angle grain boundaries that rapidly devolve into higher angle grain boundaries (Crowder et al, Mat. Res. Soc. Symp. Proc. Vol. 685E, 2001 Materials Research Society, which is incorporated in its entirety by reference). Beam-off crystallization resembles this in that the solid cools rapidly resulting in strong temperature gradients in the region behind the lateral growth front. In beam-on crystallization, on the other hand, the solid is constantly heated so there is a smaller lateral temperature gradient which furthermore is inverted at the interface since the solid absorbs more than the liquid. Without being bound to any particular theory or mode of operation, this may be the reason why no defects are formed at or near the growth front.

Preheating can be used to raise the base temperature of the film so that less energy or shorter pulse times are required to obtain the desired level of liquid/solid mix. Pre-heating mechanism include use of a heated substrate, such as a hot plate and co-irradiation, in which one radiation is used for heating and a second irradiation is used for preheating. By way of example, an exposure having a long pulse duration of low intensity is used for heating and then an exposure having a short pulse duration of high intensity is used for MPS processing. The co-irradiation can be from the same side, or opposite sides. In other embodiments, the film is preheated by irradiation from the side opposition the film.

Another controlling factor is the number of times the film is exposed to the light. Some applications use a single exposure (per unit area), while others use multiple beam irradiations to crystallize the film. For solar cells, both single and multiple irradiation methods may be used.

In one or more embodiments, the silicon film is subjected to a single FLA exposure. In order to achieve strong crystallographic texture in a single exposure, annealing conditions are selected to produce a mixed phase composition that is close to complete melting, e.g., greater than 80% vol. or greater than 90% vol. liquid. Exemplary process conditions include preheating the substrate to a high substrate temperature (in the case of a silicon film, for example, to about 400° C. to 1200° C. or 600° C. to 900° C.) and using a beam temporal profile, including slow heating and cooling, which brings the crystal close to full melting and creates large crystals that predominately have {100} surface orientations. To achieve higher levels of liquid and larger coexistence length, e.g., approaching kᵢₛ, the flash lamp is operated at low power, i.e., to provide a lower intensity light energy to the film surface, so that the system can be slowly heated and cooled, e.g., longer pulse dwell times at lower pulse intensity. Recognizing that different materials and conditions will provide different specific outcomes, it is generally observed that the resultant poly-Si films have high levels of (100) grain texture, but that other grain orientations are also present. Other orientations may exist as small grains from seeds that were located far away from {100} surface oriented seeds at the peak of mixed phase melting, by virtue of which they may have survived the mixed phase melting in the first place, but have undergone little or no growth during solidification due to the anisotropies in growth at near-equilibrium conditions. These small and possibly more defective grains are typically observed at or near grain boundaries (i.e., far from the seeds that led to large {100} grains) and are considered less harmful for solar cell applications (where the grain boundary region is already a region with shorter carrier lifetimes).

Because of the longer dwell time, there may be significant substrate heating and such methods are suited for thermally stable substrates, such as certain metal and ceramic substrates. While such substrates may not be acceptable for all applications, such as for example in display TFTs where substrate transparency is desired, no such limitation is required for solar cell applications. In one or more embodiments, steps are taken to avoid overheating the substrate, which can arise by thermal diffusion over the longer pulse dwell time, for example, by limiting the area of heating (e.g., using localized heating by patterned metal absorption layers or by patterned reflective metal layers on top) or by using thick buffer layers that may further have very low thermal conduction (e.g., porous layers).

In the techniques using flash lamps with flood exposure, repeated exposure only requires flashing the lamp more than once. With every new flashing, a portion of the crystal grains are destroyed and re-solidified from neighboring seeds. Thermodynamic factors involved include interaction between defective and less oriented grains and less defective and more oriented grains.

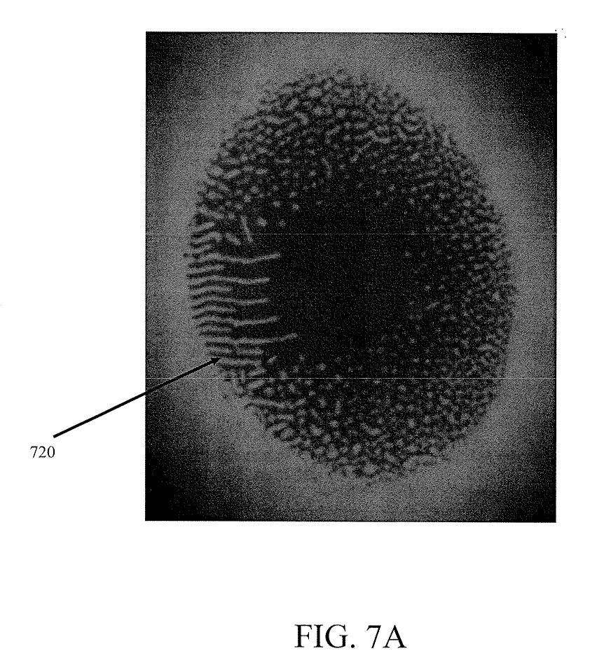

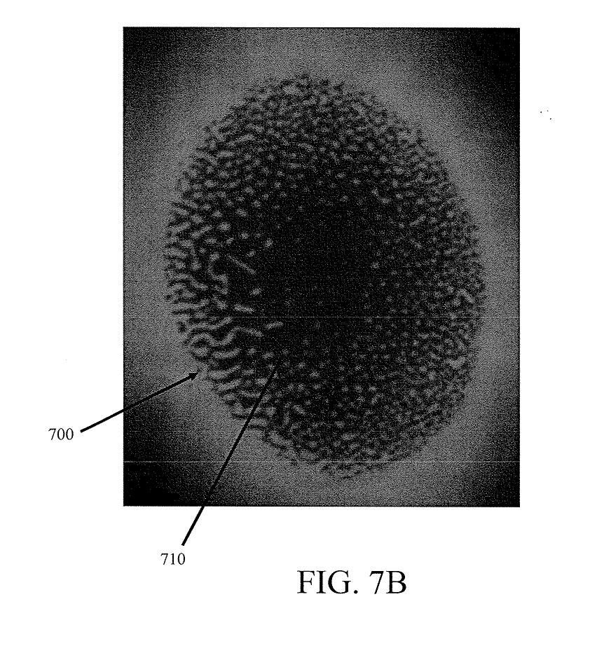

FIGS. 7A and 7B are in-situ photomicrographs of an Si thin film that is being crystallized using partial melt processing and CW complete melting, respectively. The film is being exposed to CW at a very slow scan rate CW scan, which is less relevant to partial melt processing; however, it is illustrative of what happens as the fraction of liquid decreases. The image in FIG. 7B shows complete melting. On the left side designated by arrow 700 there is clear cellular directional growth. Close to the complete melt region, at arrow 710 the solid liquid spacing is double that closer to the solidified region. Something similar happens with films subjected to partial melting as illustrated in FIG. 7A. As can be seen at arrow 720, the grains grow away in lamellar shapes to meet the periodicity commensurate with λₗₛ, which decreases with decreasing liquid content.

Traditional aluminum-induced crystallization techniques result in large grains having a high number of intra-grain defects. Thus, the resulting crystalline light absorption layer behaves like a material having a much smaller grain size. The resulting grains might be smaller than those produced by traditional methods, but the grains advantageously also have a lower density of defects and thus are more suitable for solar cells. The seed layer includes a silicon layer having a thickness of about 50 nm to 1 μm (or even thicker) or 150 nm to 500 nm having a low defect density and high degree of (100) textured grains. By way of example, the seed layer suitable for use in solar cells will have more than 90% or 95% or even 98% of the surface of the sample having an orientation within 15° of the {100} pole. The seed layer is prepared as described above.

The subsequent step, epitaxial growth of a thicker silicon layer, traditionally takes place at high temperatures, above 600° C. Recent low temperature techniques use hot wired CVD deposited layers and can be performed at around 600° C. These low temperature techniques are preferred to the high temperature techniques because of compatibility with lower-cost substrates. At the same time, the low temperature techniques, more than the high temperature versions, require a (100) textured seed material to result in proper epitaxial growth. Exemplary thickness of the epitaxially-deposited layer is between 1.5 μm to 20 μm or between 2 μm and 6 μm.

The seed layer approach is also advantageous in growing a solar cell's p-n junction or dopant gradient. The absorber layer can be grown with a different doping species and/or different concentration thereof from the seed layer and furthermore can be provided with a gradient in doping concentration by varying the relative concentration thereof in the deposition gas mixture. In this way, the p-n junction of the solar cell can be introduced. The epitaxially grown layer may also have the same doping species throughout as the seed layer and a p-n junction is later formed in a subsequent deposition step to create an emitter layer that is possibly in the amorphous phase. The absorber layer can have a different level of dopant concentration or even a gradient thereof to produce a back surface field for reducing minority carrier recombination at a back contact. The seed layer can be highly doped to simultaneously act as a back contact for the solar cell.

In one or more embodiments, the epitaxial growth phase can be prepared using epitaxial explosive crystallization. Epitaxial explosive growth takes advantage of the relative thermodynamic stabilities of amorphous and crystalline silicon to initiate and propagate an epitaxial crystalline phase through the thickness of the silicon layer. Further details of the method are found in co-pending application Ser. No. 61/012,229, entitled “Methods and Systems for Backside Laser Induced Epitaxial Growth of Thick Film”, which is hereby incorporated by reference in its entirety. One advantage of the proposed technology is that the seed material is almost fully textured in a (100) orientation, which is advantageous in the use of epitaxial explosive growth techniques.

Solar cells can use glass, as well as non-glass substrates. While the MPS methods can be used on non-glass substrates, they have to be optimized to meet the limitations of glass substrates. On the other hand, these methods are appropriate for stainless steel or ceramic substrates. FLA technology can be used on both glass and non-glass, e.g., stainless steel or ceramic, substrates.

The present application does not require using the SLS techniques. Nevertheless a hybrid mechanism combining the mentioned techniques with the SLS methods can be envisioned. MPS may result in a uniform grain size material. This is desired for optimum solar cells. SLS may further be used to create more uniform grain size films, as well as to further increase the grain size. Even though far-from-equilibrium lateral growth is known to typically result in defective growth (through twinning, stacking faults, or even complete breakdown of epitaxial growth into highly defective material), for (100) surface textured material it is known that substantially defect-free material can be achieved over at least a significant lateral growth length.

Also, the techniques may further be used to create (100) textured films for use in 3D-ICs, for example, using the hybrid SLS process or previously disclosed processes (or any derivative) to create location-controlled single-crystal islands as, for example, described in Song, et al., “Single-crystal Si islands on SiO₂ obtained via excimer-laser irradiation of a patterned Si film,” Appl. Phys. Lett. 68 (22), May 1996, pp. 3165-3167, which is hereby incorporated in its entirety by reference.

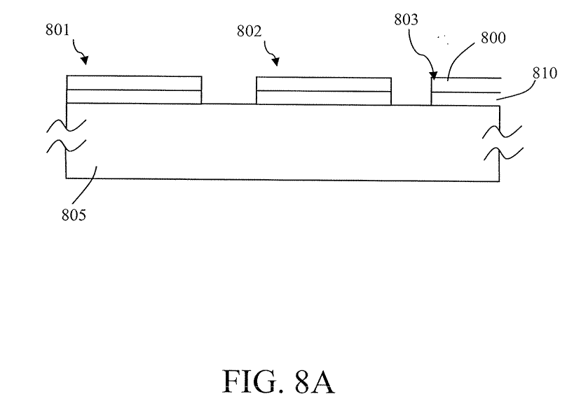

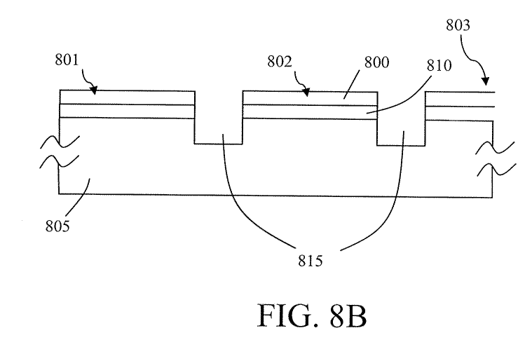

Additionally, FLA can cause unwanted lateral crystallization in a thin film. This can occur when the lateral growth or explosive crystallization extends beyond the region being irradiated. Therefore, when irradiating a film with FLA, the film can have good quality crystallization sections, corresponding to the region being irradiated, and poor quality sections, corresponding to the unwanted lateral growth. Also, these unwanted lateral growth regions also have different optical properties from the properly crystallized regions, which can complicate later irradiation processes. Therefore, in some embodiments, for example, shown in FIGS. 8A and 8B, the unwanted lateral crystallization can be reduced by providing barriers for lateral heat flow at the edges of the radiated region of a thin film 800 on a substrate 805. The barriers or isolation of the film can be provided by etching the thin film 800 or by also etching the underlying layers, for example, a buffer layer 810 (as shown in FIG. 8A). The etching of the thin film reduced irradiation heat transfer between a first section 801, a second section 802 and a third section 803. However, some heat may be transferred through the substrate. Therefore, as shown in FIG. 8B, the substrate 805 can have one or more trenches 815. These trenches 815 can further reduce heat flow between the first section 801, the second section 802 and the third sections 803, thereby further limiting unwanted lateral crystallization. Such trenches 815 can be made using conventional etching techniques or even laser scribing techniques.

This embodiment can prevent non-sharp/smeared crystallized domains. In other embodiments, because of long heat diffusion length, wide edges that are non-uniformly crystallized can form, which may prevent close tiling. For example, once a region is crystallized via explosive crystallization, the optimum energy to induce mixed phase solidification has shifted and a next radiation may thus not lead to MPS in those explosive crystallization regions. This process allows for more sharply defined crystallized regions.

Upon review of the description and embodiments of the present invention, those skilled in the art will understand that modifications and equivalent substitutions may be performed in carrying out the invention without departing from the essence of the invention. Thus, the invention is not meant to be limiting by the embodiments described explicitly above, and is limited only by the claims which follow.

What is claimed is:

1. A method of making a crystalline film, comprising:
providing a film comprising seed grains with a substantially uniform crystallographic surface orientation on a substrate;
irradiating the film using a pulsed light source to provide pulsed melting of the film under conditions to provide a plurality of solid sections and liquid sections extending throughout the thickness of the film, creating a mixed liquid/solid phase comprising one or more of the seed grains; and
allowing the mixed solid/liquid phase to solidify from the seed grains to provide a textured polycrystalline layer having the crystallographic surface orientation of the seed grains.

2. The method of claim 1, wherein providing a film comprises:
providing an amorphous film; and
subjecting the amorphous film to a radiation-induced transformation to polycrystalline silicon prior to the creation of a mixed liquid/solid phase to provide a film comprising seed grains of the substantially uniform crystallographic surface orientation.

3. The method of claim 1, wherein the mixed solid/liquid phase has a periodicity approaching a critical solid-liquid coexistence length (Xᵢₛ).

4. The method of claim 1, wherein the selected surface orientation is a {100} plane.

5. The method of claim 1, wherein the resultant textured polycrystalline layer comprises about 90% of the surface area of the film having a {100} surface orientation within at least one of about 15° of the {100} pole, about 10° of the {100} pole, and about 5° of the {100} pole.

6. The method of claim 1, wherein the conditions of irradiation are selected to provide an intensity of incident light to provide a periodicity of the liquid-solid phase that approaches λₗₛ.

7. The method of claim 1, wherein the pulsed light source is a divergent light source.

8. The method of claim 7, wherein the pulsed divergent light source comprises at least one of a flash lamp and a laser diode.

9. The method of claim 1, wherein the film comprises silicon.

10. The method of claim 1, wherein the liquid content of the mixed solid/liquid phase is in the range of at least one of about 50 vol % to less than 100 vol % and about 80 vol % to about 99 vol.

11. The method of claim 1, wherein the intensity of the divergent light source pulse is selected to provide a mixed solid/liquid phase.

12. The method of claim 1, wherein the film thickness is in the range of at least one of about 50 nm to about 1 μm and about 150 nm to about 500 nm.

13. The method of claim 1, wherein the film is exposed to at least one of a single flash lamp pulse and multiple light pulses.

14. The method of claim of claim 13, wherein a second and subsequent pulse has a higher energy density than the first light pulse.

15. The method of claim 13, wherein second and subsequent pulses are more than 20% higher energy density than the first light pulse.

16. The method of claim 13, wherein the layer is exposed to at least one of one of 2-10 light pulses and 2-4 light pulses.

17. The method of claim 1, wherein the light source pulse provides a liquid/solid mix having at least about 50 vol % liquid.

18. The method of claim 1, wherein the energy intensity of the incident light is about 2 J/cm² to about 150 J/cm².

19. The method of claim 1, wherein the mixed liquid/solid phase is achieved by selection of energy density, pulse shape, dwell time, and wavelength of the light incident to the film.

20. The method of claim 1, further comprising preheating the substrate prior to flash lamp irradiation.

21. The method of claim 21, wherein the light source comprises at least a wavelength in the range of 400-900 nm.

22. The method of claim 21, wherein the light source comprises light of a wavelength selected for absorption by one or more of an underlying heat absorption layer and the film.

23. The method of claim 1, wherein the light source comprises white light.

24. The method of claim 1, further comprising providing a metal underlayer for the film, wherein the heat of the light source is at least partially absorbed by the metal layer.

25. The method of claim 24, wherein a barrier layer is disposed between the film and the metal layer to reduce interaction of the film with the metal layer.

26. The method of claim 24, wherein the metal layer is patterned to provide heat absorption in selected areas.

27. The method of claim 1, further comprising:
irradiating the mixed liquid/solid phase with the pulsed light source.

28. The method of claim 1, wherein the thin film is divided into one or more isolated sections.

29. The method of claim 28, wherein the substrate comprises one or more trenches proximate to one or more of the isolated sections.

30. A method of making a crystalline film, comprising:
providing a film comprising seed grains of a substantially uniform crystallographic surface orientation on a substrate;
irradiating the film using a pulsed light source to provide pulsed melting of the film under conditions to provide a plurality of liquid sections and solid sections extending throughout the thickness of the film, creating a mixed liquid/solid phase having a periodicity of less than the solid-liquid coexistence length (λₗₛ) and comprising one or more of the seed grains;
allowing the mixed solid/liquid phase to solidify from the seed grains under conditions that provide a textured polycrystalline layer having the selected surface orientation; and
irradiating the film using a second pulsed light source to provide pulsed melting of the film under conditions that provide a plurality of solid sections and liquid sections extending throughout the thickness of the film, creating a mixed liquid/solid phase having a periodicity of greater than formed in the first pulse; and
allowing the mixed solid/liquid phase to solidify under conditions that provide a textured polycrystalline layer having the selected surface orientation, wherein at least one of the surface texture, grain size, and defectivity is improved in the second pulsed irradiation.

31. The method of claim 30, wherein at least one grain remains in the film after the first pulsed irradiation that is different from the selected surface orientation, and wherein the number of said different grains is reduced in the film after the second irradiation pulse.

32. The method of claim 30, wherein each of the first pulsed light source and the second pulsed light source comprise a divergent light source.

33. A method of forming a solar cell, comprising:
(a) providing a textured seed layer by:
providing a silicon film comprising seed grains of a {100} surface orientation on a substrate;
irradiating the film using a pulsed divergent light source to provide pulsed melting of the film under conditions that provide a plurality of solid sections and liquid sections extending throughout the thickness of the film, creating a mixed liquid/solid phase having a periodicity of a critical solid-liquid coexistence length (λₗₛ); and
allowing the mixed solid/liquid phase to solidify under conditions that provide a textured polycrystalline layer having the {100} surface orientation; and
(b) epitaxially growing a polycrystalline silicon layer on the textured seed layer to form a textured film.

34. A textured polycrystalline film disposed on a glass substrate, the film having at least 90% of the surface area of the film on a glass substrate oriented to within about 15° of the {100} pole.

35. A crystalline film produced by the method of claim 1.

36. A crystalline film produced by the method of claim 30.

37. A solar cell produced by the method of claim 33.
